(19) United States
(12) Patent Application Publication
(10) Pub. No.: US 2019/0058091 A1
(43) Pub. Date: Feb. 21, 2019

(54) WHITENING METHOD FOR PHOSPHOR'S COLOR AT OFF-STATE IN LIGHTING APPLICATION

(71) Applicant: SABIC Global Technologies B.V., Bergen op Zoom (NL)

(72) Inventors: Sang Hoon KIM, Seoul (KR); Ho Kyoon CHUNG, Gyeonggi-do (KR); Jo DEOK SU, Gyeonggi-do (KR); Subin JUNG, Gyeonggi-do (KR)

(21) Appl. No.: 15/760,459

(22) PCT Filed: Sep. 20, 2016
(86) PCT No.: PCT/IB2016/055613

§ 371 Date: Mar. 15, 2018

Related U.S. Application Data
(60) Provisional application No. 62/221,210, filed on Sep. 21, 2015.

(51) Int. Cl. H01L 33/50; H01L 33/32; H01L 33/62

(52) U.S. Cl. CPC H01L 33/504; H01L 2933/0091; H01L 33/62; H01L 33/32

(57) ABSTRACT

A light-emitting device and method of producing a white appearance for a light-emitting device in an off-state are disclosed. The device includes a supporting member, an organic light emitting diode (OLED) disposed on the supporting member and a color conversion layer disposed on the OLED. The color conversion layer comprises phosphor and has a non-white appearance under ambient light when the device is in an off-state. The device further includes one or more whitening layers that have a plurality of whitening particles configured to reduce the absorption of ambient light by the color conversion layer and produce a white appearance for the device in the off-state under ambient light.

### RELATED APPLICATION

The present application claims priority to and the benefit of U.S. Provisional application No. 62/221,210, “WHITENING METHOD FOR PHOSPHOR'S COLOR AT OFF-STATE IN LIGHTING APPLICATION” (filed. Sep. 21, 2015), the entirety of which is incorporated herein by reference for any and all purposes.

### TECHNICAL FIELD

The disclosure relates to light-emitting devices and more particularly, to light-emitting devices that produce white light and have a white appearance when the device is in an off-state.

### BACKGROUND

Today, organic light emitting diodes (OLEDs) are increasingly used in lighting applications because they are inexpensive and more energy efficient than other conventional lighting sources. In recent years, industry has been largely focused on the development of white OLEDs due to the high demand for the efficient production of white light. To date, there are three different types of devices using OLEDs that have been developed to produce white light. One type of white OLED has a single white emissive layer structure that produces white light. The single white emissive layer in this structure consists of a single active organic layer that is doped with different kinds of emissive materials, such as fluorescent and phosphorescent materials. Blends of polymers may be used to extend the emission spectrum to achieve white light. While the fabrication method of the single white emissive layer structure is simple and inexpensive, it is very difficult to optimize the various fabrication parameters to achieve good color rendering without significantly reducing the OLED's efficiency.

The second and most widely used white OLED is a multilayered structure composed of separate red, blue and green emitting layers. This multilayered structure produces white light through the simultaneous emission of light from each of the red, blue and green emitting layers. However, this multilayered structure tends to suffer from color stability problems due to the degradation of the emitters in each of the colored layers at different rates. This degradation of the different emitters ultimately leads to changes in the integrity of the white light over time. Furthermore, there are inherent challenges associated with the optimization of the multiple layers to obtain white light of a desired quality.

The third type of white OLED is a hybrid OLED and is formed using a color conversion layer (CCL) with a blue emitting layer to produce white light. Red and green emitting layers are not used in the hybrid OLED and only a blue emitting layer is applied to the substrate. The color conversion layer contains a phosphor material that scatters a portion of the light from the blue emitting layer. The combination of the light emitted from the phosphor material and the unabsorbed light from the blue emitting layer produces white light. Because this hybrid OLED uses only one emission layer, the fabrication process is simple and it has improved color stability.

The hybrid OLED device, however, also has some drawbacks. One major drawback is that the phosphor material in the CCL on the OLED produces a colored appearance that is often yellow or yellowish when the device is in the off-state. As an example, the device is turned on and the device produces bright white light. However, when the device is turned off (i.e., the OLED is not emitting a light), the device appears yellow under ambient light. The yellow color is due to the presence of a yellow-emitting phosphor material that is used in the color conversion layer. Again, the device may be turned on and may produces a bright white light, but when the device is turned off, the device appears red under ambient light. In this case, the red color is due to the presence of a red-emitting phosphor material instead of a yellow-emitting phosphor material used in the color conversion layer.

This phenomenon is due to the intrinsic nature of the phosphor material, which absorbs the white ambient light and converts the light to yellow when the OLED is off or the blue emitting layer is not emitting any blue light through the CCL. This phenomenon is undesirable from an aesthetic point of view because white is more desirable and is generally considered more attractive than yellow colors. Additionally, the yellow or the non-white appearance of the hybrid OLED device in the off-state tends to cause confusion among users, who may mistakenly think that the hybrid OLED does not emit white light when it is turned on.

Therefore, there is a need for improved light-emitting devices and a process for forming such devices that provide a white color when the device is in an off-state while still maintaining the luminesce efficiency of the device and the brightness of the white light. Accordingly, the disclosed light-emitting device and process is directed at overcoming one or more of these disadvantages in currently available OLEDs.

### SUMMARY

In accordance with one aspect of the disclosure, a light-emitting device is disclosed. The light-emitting device includes a supporting member having a reflective surface, an organic light emitting diode (OLED) disposed on the reflective surface, a color conversion layer disposed on the OLED, wherein the color conversion layer comprises phosphor and has a non-white appearance under ambient light when the OLED is in an off-state. The device further includes one or more whitening layers disposed over the OLED and the color conversion layer. The whitening layer(s) comprise(s) a plurality of whitening particles and are configured to whiten the appearance of the color conversion layer under ambient light when the OLED is in an off-state.

In accordance with another aspect of the disclosure, a whitening component for a light-emitting device is disclosed. The light-emitting device includes a supporting member, an organic light emitting diode (OLED) disposed on the supporting member, and a color conversion layer disposed on the OLED. The whitening component includes one or more whitening layers disposed on the color conversion layer and the OLED. The one or more whitening layers include a plurality of whitening particles that are configured to whiten the appearance of the light-emitting device in its off-state.

In accordance with another aspect of the disclosure, a method of producing a white appearance for a light-emitting device in an off-state is disclosed. The device includes a supporting member, an organic light emitting diode (OLED) disposed on the supporting member, and a color conversion layer including an inorganic phosphor material disposed on the OLED. The method includes (a) determining the total color conversion ratio of the light-emitting device, and (b) applying one or more whitening layers over the color conversion layer of the light-emitting device to form a modified light-emitting device, wherein the total color conversion ratio of the modified light-emitting device is at least 75% less than the color conversion ratio of the light-emitting device.

### BRIEF DESCRIPTION OF THE DRAWINGS

The above-mentioned and other features and advantages of this disclosure, and the manner of attaining them, will become apparent and be better understood by reference to the following description of one aspect of the disclosure in conjunction with the accompanying drawings, wherein:

FIG. 1 is a schematic illustration of a cross-sectional view of a light-emitting device without whitening layers when the device is in an off-state, according to one aspect of the present disclosure.

FIG. 2 is a graphical illustration of the transmittance and reflectance of the light-emitting device shown in FIG. 1 as a variation of wavelength.

FIG. 3 is a schematic illustration of a light-emitting device having whitening layers under ambient light when the device is in an off-state, according to an aspect of the disclosure.

FIG. 4(a) is a graphical illustration of the transmittance as a variation of wavelength of the whitening layers and color conversion layer of the light-emitting device of FIG. 4, according to an aspect of the disclosure.

FIG. 4(b) is a graphical illustration of the reflectance as a variation of wavelength of the whitening layers and color conversion layer of the light-emitting device of FIG. 4, according to an aspect of the disclosure.

### DETAILED DESCRIPTION

Light-emitting devices, especially organic light emitting devices (OLEDs) that produce white light are disclosed. In one aspect of the present disclosure, hybrid OLEDs or OLEDs that use a blue emitting layer and a color conversion layer containing phosphor materials are disclosed. Although the discussion of the preferred embodiments relates to OLEDs, it will be understood by those skilled in the art that the disclosure is in fact applicable to any device, especially those emitting light, and especially those emitting white light.

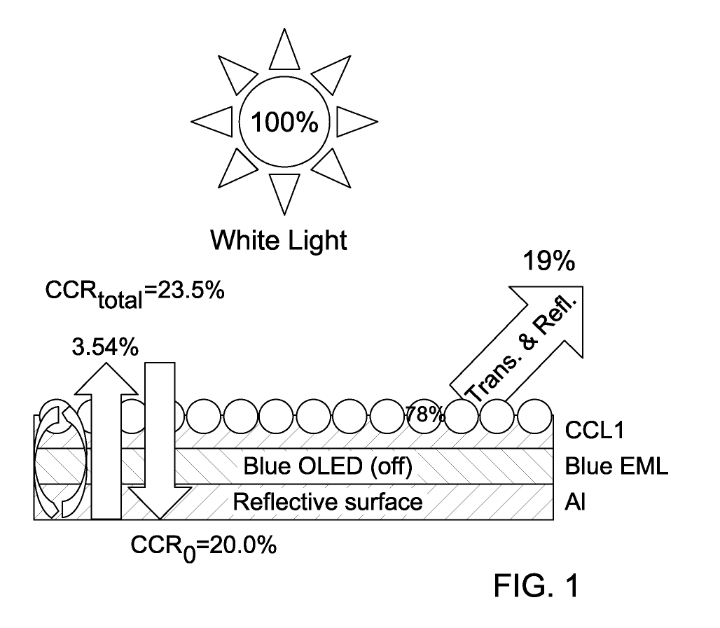

Referring now to FIG. 1, a light-emitting device is shown. The light-emitting device may include: a supporting member, an organic light emitting diode (OLED) disposed on the supporting member, and a color conversion layer disposed on the OLED. The light-emitting device may further include at least one whitening layer (not shown). The whitening layer may be disposed on the OLED and the color conversion layer. The light-emitting device has a white appearance when the device is in its off-state.

The light-emitting device may have an on-state wherein the device emits light and an off-state wherein the device does not emit any light. When the light-emitting device is in its on-state, the OLED is illuminated. Conversely, when the light-emitting device is in its off-state, the OLED is not illuminated. In one aspect of the present disclosure, the light-emitting device emits white light in its on-state. In another aspect, the light-emitting device does not emit any light in its off-state but has white appearance in its off-state. The light-emitting device may be powered by a variety of methods known in the art. For example, the OLED may be connected to a circuit or an element that provides current to the OLED thereby illuminating the OLED when the device is turned on.

In one aspect, the OLED is a blue OLED, also referred to as a blue light emitter and is configured to emit blue light. For example, the OLED emits light in the blue portion of the visible spectrum approximately 400-480 nm. As explained in further detail below, the emission of blue light may be used to produce white light. The present disclosure may, however, be implemented using various illumination sources such as fluorescent lights or light emitting diodes that use arrays of red, green or blue OLEDs. In one aspect of the present invention, the light-emitting device may use an array of red, green, and blue OLEDs that collectively produce white light. For example, aspects of the present disclosure contemplate use of any color emitter.

In some aspects, the light-emitting device may include one OILED or more than one OLED. Any semiconductor material known in the art may be used to form the OLED. For example, gallium nitride (GaN) may be used to form a blue OLED for use with the present disclosure. The color of the light emitted from the OLED is generally a function of the semiconductor materials used to form the OLED. The OLED may emit light in various configurations and the disclosure is not limited in this regard. For example, the OLED may be a bottom-emitting OLED, a top-emitting OLED, a side-emitting OLED or a combination thereof.

The light-emitting device includes a supporting member. The supporting member is adapted to support the OLED or an array of OLEDs. For example, the OLED may be disposed on the support member as shown in FIG. 1. The supporting member may have at least one reflective surface. In one aspect, the OLED may be disposed on the reflective surface of the supporting member. Suitable materials for the supporting member may include, but are not limited to glass, polycarbonate, polyethylene terephthalate, polyethersulfone, polyethylene naphthalate, and poly(methyl methacrylate).

The light-emitting device further includes a color conversion layer. The color conversion layer is arranged to receive light or radiation from the OLED. The color conversion layer may be disposed on the OLED as shown in FIG. 1 as “CCL1.” Alternatively, the color conversion layer may be spaced apart from the OLED.

The color conversion layer is configured to convert at least a portion of the light emitted from the OLED to a different color. For example, the present disclosure contemplates that the color conversion layer is configured to produce white light from the emission of non-white light from the OLED. In one aspect, the color conversion layer produces white light from the blue light emitted from a blue OLED.

The color conversion layer may comprise a film of fluorescent or phosphorescent material which efficiently absorbs higher energy photons (e.g. blue light and/or yellow light) and reemits photons at lower energy (e.g. at green and/or red light) depending on the materials used. That is, the color conversion layer may absorb light emitted by an organic light emitting device (e.g. a white OLED) and remit the light (or segments of the wavelengths of the emission spectrum of the light) at a longer wavelength.

In some aspects, the light-emitting device may include more than one color conversion layer. The color conversion layer includes a film or layer of color conversion material that is configured to convert at least some of the light emitted by the OLED into light having a different wavelength. For example, the color conversion layer may include a layer of material that is configured to convert the light emitted by the OLED to a higher or lower wavelength. In one aspect of the disclosure, the color conversion material is a phosphor material. For example, if the OLED emits blue light in the blue spectral range of 450-490 nm, then the color conversion layer may contain a layer of phosphor material for converting some of this radiation to a different spectral range. Preferably, the phosphor material is configured to convert most or all of the radiation from the OLED to the desired spectral range. Phosphor materials suitable for this purpose are generally known in the art and may include, but are not limited to yttrium aluminum garnet (YAG) phosphors.

The phosphor material is typically in the form of a powder. The phosphor powder may be composed of phosphor particles, phosphor microparticles, phosphor nanoparticles or combinations thereof. The phosphor particles or phosphor microparticles may have an average diameter that ranges in size from 1 micron to 100 microns. In one aspect of the present disclosure, the average diameter of the phosphor particles is less than 50 microns. In another aspect of the present disclosure, the average diameter of the phosphor particles is less than 20 microns. In yet another aspect of the present disclosure, the average diameter of the phosphor particles is less than 10 microns. In yet another aspect of the present disclosure, the average diameter of the phosphor nanoparticles used in the phosphor powder ranges from 10 nm to 900 nm. The size of the phosphor particles is generally selected based on the desired thickness of the color conversion layer and/or the overall thickness of the color conversion layer.

The phosphor powder may be dispersed in a binder material that is useful in forming a film or a sheet. A uniform distribution of the phosphor powder in the binder material and throughout the color conversion layer is generally preferred to achieve a consistent color quality, of light from the light-emitting device. More uniform color quality and brightness.

The binder material may be organic or inorganic. In one aspect of the present disclosure the binder material is transparent or translucent. In another aspect of the present disclosure, the binder may be a uv-curable binder. The binder material may also be curable thermally.

Examples of binder materials suitable for use with the phosphor material may include, but are not limited to silicone resin, epoxy resin, polyallylate resin, PET modified polyallylate resin, polycarbonate resin (PC), cyclic olefin, a polyethylene terephthalate resin (PET), polymethylmethacrylate resin (PMMA), a polypropylene resin (PP), modified acryl resin, polystyrene resin (PE), and acrylonitrile-styrene copolymer resin (AS). The binder material may include combinations or mixtures of these and/or other suitable materials. For example, additives may be added to the binder material to improve or alter certain properties of the color conversion layer as needed.

In one aspect of the disclosure, the color conversion layer may cause the device to have a non-white appearance when the device is in an off-state. For example, phosphor material in the color conversion layer may be responsible for the non-white appearance or the yellow color of the light-emitting device. As set forth below, a whitening component or one or more whitening layers are included in the light-emitting device to whiten the appearance of the device in its off-state and create a more aesthetically pleasing device.

The light-emitting device further includes one or more whitening layers disposed over the OLED and the color conversion layer. The whitening layers may be directly deposited onto the color conversion layer or the whitening layers may be spaced apart from the color conversion layer. For example, the whitening layers may be separated from the color conversion layer by other materials or components that are present in the light-emitting device.

The whitening layers are configured to whiten the appearance of the light-emitting device in its off-state. The whitening layers reduce the absorption of ambient light by the color conversion layer to produce a white appearance for the device in the off-state. In one aspect, only one whitening layer may be necessary to provide a white appearance in the off-state. In another aspect, multiple layers may be needed to achieve a white appearance for the device in the off-state.

The whitening layer comprises a plurality of whitening particles. In one aspect of the present disclosure, the whitening particles may include TiO₂, Al₂O₃, ZrO, ZnO ZrO₂ or mixtures thereof. Other materials may be used for the whitening particles if they are white or have a whitening effect on the light-emitting device under ambient light. The appearance of the light-emitting device having a color conversion layer using phosphor should appear much whiter when the light-emitting device is turned off. Additionally, the whitening particles and other materials used to form the whitening layer are preferably selected such that they do not adversely affect the efficiency or the brightness of the light-emitting device.

The whitening particles may be present in the whitening layer in an amount from 5% to up to 50% by weight based on the total weight of the of the whitening layer. Generally, as the amount of the whitening particles increases, a whiter appearance results when the light-emitting device is in the off-state.

The whitening particles may be microparticles, nanoparticles or combinations thereof. The whitening particles may have an average diameter that ranges in size from 1 micron to 100 microns. In one aspect of the present disclosure, the average diameter of the whitening particles is less than 50 microns. In another aspect of the present disclosure, the average diameter of the whitening particles is less than 20 microns. In yet another aspect of the present disclosure, the average diameter of the whitening particles is less than 10 microns. In yet another aspect of the present disclosure, the average diameter of the whitening nanoparticles used in the whitening layers ranges from 10 nm to 900 nm. In some aspects, the size of the whitening particles and the density of the whitening particles in the whitening layers may at least in part determine the thickness and/or the whitening performance of the whitening layer. Therefore, it may be desirable to optimize the number of the whitening layers required to whiten the appearance of the device in its off-state. This process of optimizing the number of whitening layers is described in further detail below.

The whitening particles may be mixed with a binder material and/or an encapsulant. The binder material used in the color conversion layer may be the same binder material used in the whitening layers. An encapsulant material may provide a moisture and/or oxygen barrier to the light-emitting device to protect the device from degradation. The encapsulant may be composed of organic or inorganic materials. For example, the encapsulant may be made of silicone, epoxy, glass, plastic or other materials. The encapsulant is preferably transparent or translucent. The whitening particles may be uniformly distributed throughout the binder material and/or encapsulant to ensure a uniform white color.

The one or more whitening layers may be used to compose a whitening assembly for a light-emitting device to give the device a white appearance in its off-state. For example, the whitening layers may be fabricated separately and then subsequently attached to an existing light-emitting device. One important advantage of the present disclosure is that one or more whitening layers or the whitening assembly may be used to impart a white appearance to light-emitting devices with only a simply modification without replacing the device in its entirety.

The hybrid OLED shown in FIG. 1 has a blue emission layer for the OLED that includes GaN. The blue OLED is mounted on the reflective surface of an aluminum substrate. The device also has one color conversion layer (“CCL1”) composed of phosphor material that is a YAG phosphor. The device is shown under 100% white ambient light (sunlight) when the device is in the off-state (no light emission).

When the device is turned off, sunlight strikes the surface of the device and the light is reflected, transmitted or absorbed by the device. The transmittance and the reflectance of the device were measured by UV-VIS spectrometer with integrated sphere apparatus and method. The transmittance of the device shown in FIG. 1 was measured at 78% and the reflectance was measured at 19%. Therefore, 3% of the total amount of ambient light was considered to be lost.

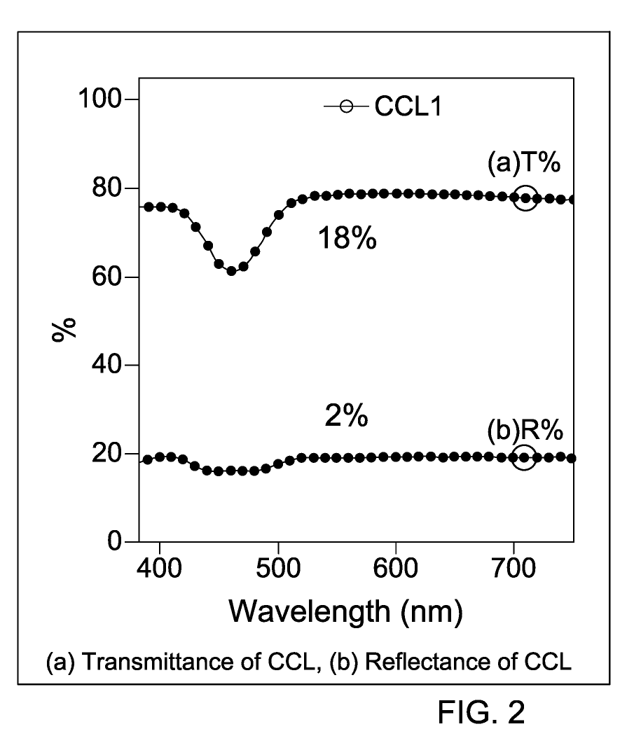

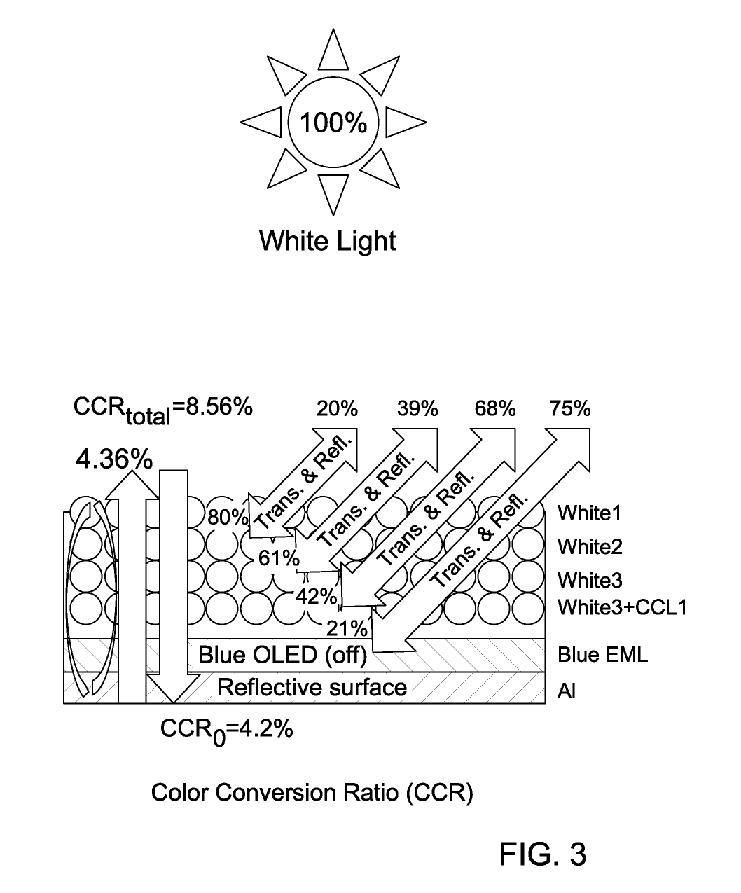

FIG. 3 shows the spectrophotometric transmittance and reflectance curves of the color conversion layer of the device in FIG. 1 as a variation of wavelength in the visible spectrum from about 390 nm to about 700 nm. As shown in FIG. 2, curve (a) corresponds to 18% transmittance and curve (b) corresponds to 2% reflectance for the color conversion layer. The sum of the transmittance and the reflectance or the absorbance of the color conversion layer is 20% within the visible spectrum. Therefore, approximately 80% of the ambient light that strikes the surface of the color conversion layer is absorbed by the color conversion layer and produces a yellow color.

FIG. 2 shows that the color conversion layer has a decline in both the transmittance (a) and reflectance (b) curves when the wavelength is around 460 nm. The decline is more pronounced, however, in the transmittance (a) curve than in the reflectance (b) curve. The decline in in the transmittance (a) and reflectance (b) curves is characteristic of the blue emission layer in combination with the yellow color of the phosphor containing color conversion layer.

The light-emitting device may be designed such that the amount of transmittance and reflectance remain predominantly constant at the targeted wavelength in order to mitigate the yellow appearance of the device under ambient light. This may be achieved using the approach set forth below. This approach may also be used to confirm that a certain number of whitening layers has removed the yellow appearance and created a white appearance for the device in the off-state.

The light-emitting device having only one color conversion layer has a total color conversion ratio of 23.5 as calculated using Equations 1-1 and 1-2.

$$\begin{matrix}Color Conversion {Ratio}_{0} ( {CCR}_{0} ) = Light \% \times {Ccof}_{—} CCL 1 = 20 \% & ( 1 \text{-} 1 ) \\ CCRn = {CCR}_{0} + {lim}_{n \to ∞} a \frac{( {r}^{n} - 1 )}{( r - 1 )} = 30.63 \\ {CCR}_{0} = 20 \% , r = 0.186 , a = 8.65 \% & ( 1 \text{-} 2 )\end{matrix}$$

In Equation 1-1, the color conversion ratio (CCR₀) was initially calculated without considering any light that may be recycled internally within the device. The C_{cof}_{_}_{CCL}1 is the conversion coefficient (absorbance) of the color conversion layer, which was measured as 20% using Xenon lamp in integrated sphere. Therefore, the CCR₀ was calculated as 20%.

In Equation 1-2, the total color conversion ratio (CCRₙ) was calculated using a geometric sequence to account for the internal recycling of light. In Equation 1-2, (a) is the first term or first number in the geometric sequence (CCR₁) and (r) is the common ratio in the geometric sequence. Here, the first term (a) or CCR₁ was calculated as 8.65% and CCR₂ was calculated as 1.6. The common ratio (r) was calculated as CCR₂/CCR₁ or 0.186. Using these values an additional 10.63% of color conversion ratio was attributed to the recycled light, resulting in 30.63% for the total color conversion ratio. At 30.63% for total color conversion ratio, it was noted that the device had a yellowish appearance under ambient light. Whitening layers were then added to the color conversion layer to achieve a white appearance and reduce the total color conversion ratio of the device to less than 30.63%.

Referring now to FIG. 3, a schematic illustration of the same structure from FIG. 1 with the addition of three whitening layers is shown. Here again, the structure is in its off-state and is shown under ambient white light or sunlight.

“White1” refers to the first whitening layer, i.e., the whitening layer that is applied after the second whitening layer and is the furthest from the color conversion layer. “White2” refers to the second whitening layer, i.e., the whitening layer that is applied second and is between the first and third whitening layers. “White3” refers to the third whitening layer, i.e., the whitening layer that is applied first and is the closest to the color conversion layer. “White3+CCL1” refers to the color conversion layer (CCL1), which is adjacent to White3. Direct application of the whitening layer onto the color conversion layer may cause the whitening layer to impregnate or partially penetrate the color conversion layer.

The whitening layers reduce the transmittance and increase reflectance of the structure. For example, adding three whitening layers to the phosphor-containing color conversion layer reduced the transmittance of ambient light from 78% to 21% and increased the reflectance of ambient light from 19% to 75%. The ambient light lost by the device was approximately 4%.

The color conversion ratios were then re-calculated using the Equations 2-1 and 2-2.

$$\begin{matrix}Color Conversion {Ratio}_{0} ( {CCR}_{0} ) = Light \% \times {Ccof}_{{—}_{{CCL}_{1}}} = 4.2 \% & ( 2 \text{-} 1 ) \\ {CCR}_{n} = {CCR}_{0} + {lim}_{n \to ∞} a \frac{( {r}^{n} - 1 )}{( r - 1 )} = 7.64 \% \\ {CCR}_{0} = 4.2 \% , r = 0.735 , a = 0.91 \% & ( 2 \text{-} 2 )\end{matrix}$$

In Equation 2-1, the C_{cof}_{_}_{CCL}1 or the conversion coefficient (absorbance) of the color conversion layer as 20% was used and the CCR₀ or the color conversion ratio without any internal recycling of light was calculated as 4.2%. In Equation 2-1, a is the first term or first number in the geometric sequence (CCR₁) and r is the common ratio in the geometric sequence. After adding the whitening layers to the device, the first term a or CCR₁ was calculated as 0.91%. The common ratio (r) was calculated as CCR₂/CCR₁ or 0.735. Using Equation 2-2, the total color conversion ratio (including recycled light) was calculated as 7.64%. These results show a reduction of up to 75% in the total color conversion ratio with the addition of the whitening layers.

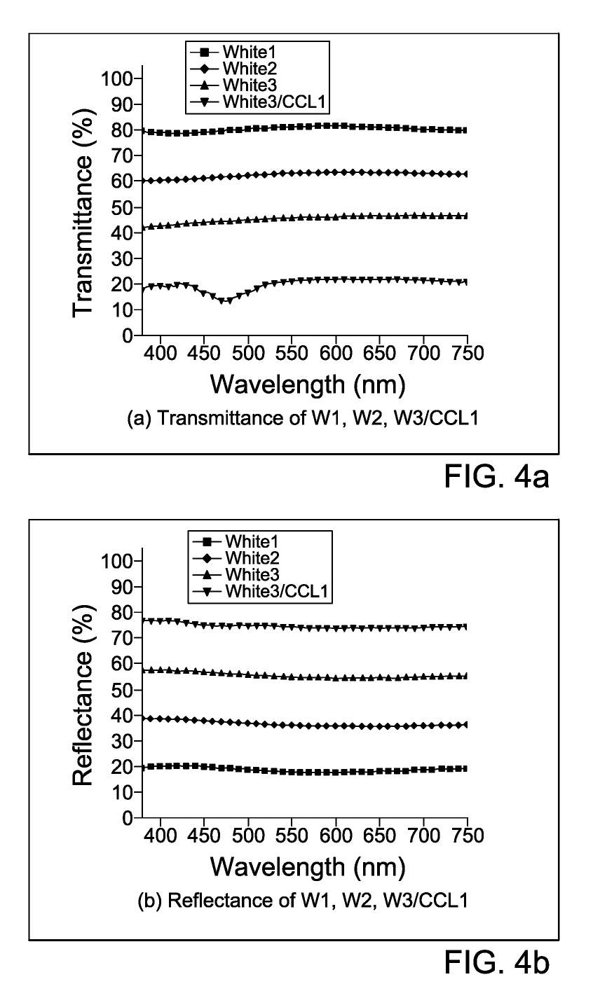

FIGS. 4(a) and 4(b) show the spectrophotometric transmittance and reflectance curves, respectively for the various layers of the structure in FIG. 3 for wavelengths in the visible spectrum from about 390 nm to about 700 nm. FIG. 4(a) shows the transmittance curves for each of the three whitening layers (White1, White2, White3) and the color conversion layer (White3/CCL1). FIG. 4(b) shows the transmittance curves for each of the three whitening layers (White1, White2, White3) and the color conversion layer (White3/CCL1).

As shown in FIGS. 4(a) and 4(b), the transmittance and reflectance curves for each of the whitening layers demonstrate a more linear relationship across the visible spectrum compared to the transmittance and reflectance curves shown in FIG. 2 for the color conversion layer without any whitening layers. It can be seen that the transmittance and reflectance values for the whitening layers are predominantly constant across the visible spectrum.

There is, however, a slight decline in reflectance and transmittance at 460 nm for the single whitening layer (White3/CCL1) shown in FIGS. 4(a) and 4(b). Again, this decline is characteristic of the presence of the blue emission layer for the device. As shown in FIGS. 4(a) and 4(b), the decline in transmittance is more pronounced than it is for reflectance. For example, the decline observed at 460 nm in transmittance was 3.73% and the decline in reflectance was 0.47%. Therefore, the total internal recycle for the structure was calculated as 4.2% or the sum of the 3.73% for transmittance and 0.47% for reflectance. It is clear that the decline in the transmittance curves is suppressed with the addition of whitening layers. These results, in particular the increased linear relationship for the transmittance and reflectance of the device as a variation of wavelength confirms that the addition of the whitening layers has resulted in a white appearance for the device in the off-state.

A side-by-side color comparison was conducted of the light-emitting device in the off state without whitening layers and up to three whitening layers. As observed, the color of the device with only the color conversion layer appeared yellow. The device color appeared increasingly less yellow and/or whiter as the whitening layers were added. It is noted, however, that device only appears white after three whitening layers are added.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

### Definitions

It is to be understood that the terminology used herein is for the purpose of describing particular aspects only and is not intended to be limiting. As used in the specification and in the claims, the term “comprising” can include the embodiments “consisting of” and “consisting essentially of.” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, alloys, reaction products, and the like.

Ranges can be expressed herein as from one particular value to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated ±5% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

As used herein, the term “light” means electromagnetic radiation including ultraviolet, visible or infrared radiation.

As used herein, the term “transparent” means that the level of transmittance for a disclosed composition is greater than 50%. In some embodiments, the transmittance can be at least 60%, 70%, 80%, 85%, 90%, or 95%, or any range of transmittance values derived from the above exemplified values. In the definition of “transparent”, the term “transmittance” refers to the amount of incident light that passes through a sample measured in accordance with ASTM D1003 at a thickness of 3.2 millimeters.

Unless otherwise stated to the contrary herein, all test standards are the most recent standard in effect at the time of filing this application.

Aspects

The present disclosure comprises at least the following aspects.

Aspect 1. A light emitting device comprising: a supporting member; an organic light emitting diode (OLED) disposed on the supporting member; a color conversion layer disposed on the OLED, wherein the color conversion layer has a non-white appearance under ambient light; one or more whitening layers disposed over the OLED and the color conversion layer, wherein the one or more whitening layers comprises a plurality of whitening particles and is configured to whiten the appearance of the device in a off-state under ambient light.

Aspect 2. The device of aspect 1, wherein the one or more whitening layers is configured to reduce the absorption of ambient light by the color conversion layer and produce a white appearance when the device is in the off-state under ambient light.

Aspect 3. The device of aspects 1 or 2, wherein the OLED is configured to emit light at a first color and the color conversion layer is configured to convert at least a portion of the first color to a second color.

Aspect 4. The device of aspect 3, wherein the first color is a non-white color and the second color is white.

Aspect 5. The device of any of the preceding aspects, wherein the total color conversion ratio of the device in the off-state under ambient light is at least half the total color conversion ratio of a comparator light-emitting device in the off-state under ambient light that does not comprise whitening layers.

Aspect 6. The device of any of the preceding aspects, wherein the total color conversion ratio of the device in the off-state under ambient light is at least one-third the total color conversion ratio of a comparator light-emitting device in the off-state under ambient light that does not comprise whitening layers.

Aspect 7. The device of any of the preceding aspects, wherein the one or more whitening layers reduces the color conversion ratio of the device in the off-state under ambient light by at least 50%.

Aspect 8. The device of any of the preceding aspects, wherein the one or more whitening layers reduces the color conversion ratio of the device in the off-state under ambient light up to 70%.

Aspect 9. The device of any of the preceding aspects, wherein the color conversion ratio of the device in the off-state under ambient light is less than 20.

Aspect 10. The device of any of the preceding aspects, wherein the color conversion ratio of the device in the off-state under ambient light is less than 10.

Aspect 11. The device of any of the preceding aspects, wherein the total thickness of the one of more whitening layers ranges from 10 microns to 150 microns.

Aspect 12. The device of any of the preceding aspects, wherein the whitening particles comprise TiO2, Al2O3, ZrO, ZnO or mixtures thereof.

Aspect 13. The device of any of the preceding aspects, wherein the average diameter of the whitening particles is less than 50 microns.

Aspect 14. The device of any of the preceding aspects, wherein the average diameter of the whitening particles is less than 20 microns.

Aspect 15. The device of any of the preceding aspects, wherein the one or more whitening layers and/or the color conversion layer comprises a binder material.

Aspect 16. The device of aspect 15, wherein the binder material is a polymeric binder material that is thermally curable or UV curable.

Aspect 17. The device of aspect 15 wherein the color conversion layer and the one or more whitening layers comprises the same binder material.

Aspect 18. The device of aspect 15, wherein the color conversion layer and the one or more whitening layers comprises different binder materials.

Aspect 19. The device of aspects 1-14, wherein the supporting member has reflective surface and the OLED is disposed on the reflective surface.

Aspect 20. The device of aspects 1-14 and 19, wherein the supporting member comprises glass, acrylic, aluminum or combinations thereof.

Aspect 21. The device of aspects 1-14 and 19-20, wherein the one or more whitening layers reduce the transmittance and increase the reflectance of ambient light when the device is in an off-state relative to a comparator light-emitting device that does not comprise a whitening layer.

Aspect 22. The device of aspect 21, wherein the transmittance for the device is reduced by at least 50% relative to the comparator light-emitting device.

Aspect 23. The device of aspect 21 wherein the reflectance for the device is at least 200% more than the reflectance for the comparator light-emitting device.

Aspect 24. The device of aspects 1-14 and 19-20, wherein the OLED is a top-emitting OLED.

Aspect 25. The device of aspects 1-14, 19-21 and 24, wherein the OLED is a blue OLED comprising GaN.

Aspect 26. The device of aspects 1-14, 19-21 and 24-25, wherein the color conversion layer comprises a YAG phosphor material.

Aspect 27. The device of aspects 1-14, 19-21 and 24-26, wherein the transmittance of ambient light for the device in the off-state is at least 20%.

Aspect 28. The device of aspects 1-14, 19-21 and 24-27, wherein the reflectance of ambient light for the device in the off-state is at least 70%.

Aspect 29. A whitening component for a light-emitting device comprising a supporting member, an organic light emitting diode (OLED) disposed on the supporting member, and a color conversion layer disposed on the OLED, wherein the whitening component comprises one or more whitening layers disposed on the color conversion layer, each whitening layer comprising a plurality of whitening particles dispersed in a binder material and configured to whiten the appearance of the device in the off-state under ambient light.

Aspect 30. A process of fabricating a light-emitting device comprising: forming a color conversion layer comprising a phosphor material over an organic light emitting diode (LED); and applying one or more whitening layers over the color conversion layer and the OLED until the appearance of the device in the off-state is white.

Aspect 31. The process of aspect 30, further comprising determining the number of the whitening layers by reducing the total color conversion ratio of the device in the off-state under ambient light by at least 50%.

Aspect 32. The process of aspect 31, wherein the transmittance of the light-emitting device as a variation of wavelength has a substantially linear relationship.

Aspect 33. The process of aspect 31, wherein the reflectance of the light-emitting device as a variation of wavelength has a substantially linear relationship.

Aspect 34. The process of aspect 31, wherein the transmittance and the reflectance of the light-emitting device as a variation of wavelength has a substantially linear relationship.

Aspect 35. The method of producing a white appearance for a light-emitting device in an off-state, wherein the device comprises a supporting member, an organic light emitting diode (OLED) disposed on the supporting member, and a color conversion layer including an inorganic phosphor material disposed on the OLED, the method comprising: (a) determining the total color conversion ratio of the light-emitting device; and (b) applying one or more whitening layers over the color conversion layer of the light-emitting device to form a modified light-emitting device, wherein the total color conversion ratio of the modified light-emitting device is at least 75% less than the color conversion ratio of the light-emitting device.

Aspect 36. The method of aspect 35, wherein the applying one or more whitening layers over the color conversion layer of the light-emitting device to form a modified light-emitting device, further comprises (a) determining the total color conversion ratio of the modified light-emitting device; (b) comparing the color conversion ratios of the light-emitting device and the modified light emitting device and (c) reapplying whitening layers over the color conversion layer until the total color conversion ratio of the modified light-emitting device is at least 75% less than the color conversion ratio of the light-emitting device.

Aspect 37. The method of aspect 36, wherein the determining the total color conversion ratio of the light-emitting device and the determining the total color conversion ratio of the modified light-emitting device comprises: (a) determining an initial color conversion ratio (CCR₀) using Equation 1 wherein C_{cof}_{_}_{CCL}1 is the measured absorbance of the color conversion layer and Light represents a percentage of light exposed on the light-emitting device or the modified light-emitting device

(CCR₀)=Light %×Ccof_CCL1 Equation 1;

(b) determining the total color conversion ratio using Equation 2 by creating a geometric sequence having a plurality of terms each representing a value for the scattering of light inside the light-emitting device or the modified light-emitting device, wherein a represents the first term, r represents the common ratio and n represents the number of terms in the geometric sequence

$$CCRn = {CCR}_{0} + {lim}_{n \to ∞} a \frac{( {r}^{n} - 1 )}{( r - 1 )} . \qquad Equation 2$$

We claim:

1. A light-emitting device comprising:
a supporting member;
an organic light emitting diode (OLED) disposed on the supporting member;
a color conversion layer disposed on the OLED, wherein the color conversion layer has a non-white appearance under ambient light; and
one or more whitening layers disposed over the OLED and the color conversion layer, wherein the one or more whitening layers comprises a plurality of whitening particles and the one or more whitening layers is configured to reduce the absorption of ambient light by the color conversion layer and produce a white appearance for the device in an off-state under ambient light.

2. The device of claim 1, wherein the OLED is configured to emit light at a non-white color and the color conversion layer is configured to convert at least a portion of the non-white color to white.

3. The device of claim 1, wherein the total color conversion ratio of the device in the off-state under ambient light is at least half the total color conversion ratio of a comparator light-emitting device in the off-state under ambient light that does not comprise whitening layers.

4. The device of claim 1, wherein the one or more whitening layers reduces the color conversion ratio of the device in the off-state under ambient light by at least 50%.

5. The device of claim 1, wherein the one or more whitening layers reduces the color conversion ratio of the device in the off-state under ambient light up to 75%.

6. The device of claim 1, wherein the color conversion ratio of the device in the off-state under ambient light is less than 20.

7. The device of claim 1, wherein the color conversion ratio of the device in the off-state under ambient light is less than 10.

8. The device of claim 1, wherein the whitening particles comprise TiO₂, Al₂O₃, ZrO, ZnO or mixtures thereof.

9. The device of claim 1, wherein the average diameter of the whitening particles is less than 50 microns.

10. The device of claim 1, wherein the supporting member comprises glass, acrylic, aluminum or combinations thereof.

11. The device of claim 1, wherein the OLED is a blue OLED comprising GaN and the color conversion layer comprises a YAG phosphor material.

12. The device of claim 1, wherein the transmittance of ambient light for the device in the off-state is at least 20% and the reflectance of ambient light for the device in the off-state is at least 70%.

13. The device of claim 1, wherein the transmittance and the reflectance of the light-emitting device as a variation of wavelength has a substantially linear relationship.

14. The device of claim 1, wherein the one or more whitening layers reduce the transmittance and increase the reflectance of ambient light when the device is in an off-state relative to a comparator light-emitting device that does not comprise a whitening layer.

15. The device of claim 14, wherein the transmittance for the device is reduced by at least 50% relative to the comparator light-emitting device.

16. The device of claim 14, wherein the reflectance for the device is at least 200% more than the reflectance for the comparator light-emitting device.

17. A whitening component for a light-emitting device comprising a supporting member, an organic light emitting diode (OLED) disposed on the supporting member, and a color conversion layer disposed on the OLED, wherein the whitening component comprises one or more whitening layers disposed on the color conversion layer, each whitening layer comprising a plurality of whitening particles dispersed in a binder material and configured to whiten the appearance of the device in the off-state under ambient light.

18. The method of producing a white appearance for a light-emitting device in an off-state, wherein the device comprises a supporting member, an organic light emitting diode (OLED) disposed on the supporting member, and a color conversion layer including an inorganic phosphor material disposed on the OLED, the method comprising:
(a) determining the total color conversion ratio of the light-emitting device; and
(b) applying one or more whitening layers over the color conversion layer of the light-emitting device to form a modified light-emitting device, wherein the total color conversion ratio of the modified light-emitting device is at least 75% less than the color conversion ratio of the light-emitting device.

19. The method of claim 18, wherein the applying one or more whitening layers over the color conversion layer of the light-emitting device to form a modified light-emitting device further comprises:
(a) determining the total color conversion ratio of the modified light-emitting device;
(b) comparing the color conversion ratios of the light-emitting device and the modified light emitting device; and
(c) reapplying whitening layers over the color conversion layer until the total color conversion ratio of the modified light-emitting device is at least 75% less than the color conversion ratio of the light-emitting device.

20. The method of claim 19, wherein the determining the total color conversion ratio of the light-emitting device and determining the total color conversion ratio of the modified light-emitting device comprises:
(a) determining an initial color conversion ratio (CCR₀) using Equation 1 wherein C_{cof}_{_}_{CCL}1 is the measured absorbance of the color conversion layer and Light represents a percentage of light exposed on the light-emitting device or the modified light-emitting device
(CCR₀)=Light %×Ccof_CCL1 Equation 1; and
(b) determining the total color conversion ratio using Equation 2 by creating a geometric sequence having a plurality of terms each representing a value for the scattering of light inside the light-emitting device or the modified light-emitting device, wherein a represents the first term, r represents the common ratio and n represents the number of terms in the geometric sequence
$$CCRn = {CCR}_{0} + {lim}_{n \to ∞} a \frac{( {r}^{n} - 1 )}{( r - 1 )} . \qquad Equation 2$$
